(19) United States
(12) Patent Application Publication
(10) Pub. No.: US 2019/0096546 A1
(43) Pub. Date: Mar. 28, 2019

(54) 2-CORE SHIELDED CABLE AND WIRE HARNESS

(71) Applicant: Yazaki Corporation, Tokyo (JP)

(72) Inventor: Taketo KUMADA, Susono-shi (JP)

(73) Assignee: Yazaki Corporation, Tokyo (JP)

(21) Appl. No.: 16/104,458

(22) Filed: Aug. 17, 2018

(30) Foreign Application Priority Data
Sep. 25, 2017 (JP) 2017-183262

(51) Int. Cl. H01B 11/10; H01B 7/00; H01B 7/18; H05K 9/00

(52) U.S. Cl. CPC H01B 11/10; H05K 9/0098; H01B 7/18; H01B 7/0045

(57) ABSTRACT

A 2-core shielded cable and a wire harness is provided. The 2-core shielded cable is equipped with two insulated electric wires, a metal film which is provided along a length of the electric wire so as to cover the two electric wires, and a sheath which is formed around the metal film in a filled state. The metal film has a film and a metal layer. The thickness of the film is larger than or equal to 20 μm.

### CROSS-REFERENCES TO RELATED APPLICATIONS

This application is a based on and claims priority from Japanese Patent Applications No. 2017-183262 filed on Sep. 25, 2017, the entire contest of which are incorporated herein by reference.

### BACKGROUND OF THE INVENTION

### 1. Technical Field

The present invention relates to a 2-core shielded cable and a wire harness.

### 2. Description of the Related Art

Two-core shielded cables for high-speed digital signal transmission are known which aim to improve leakage attenuation characteristic of a case that differential signals are applied to them. Such 2-core shielded cables are equipped with two electric wires, a metal foil that surrounds the two electric wires, a metal braid formed on the metal foil, and a sheath formed on the metal braid. Since such 2-core shielded cables are used for transmitting high-frequency signals, with further consideration of the skin effect and the return current, it is effective to use a metal foil having a smooth surface.

Herein, multi-core (three or more cores) shielded cables are also known (for example, see Patent documents 1-3). Patent document 1 discloses a shielded cable in which each pair of electric wires is shielded by a metal foil and a number of shielded pairs of electric wires are arranged so as to assume a circle.

Patent document 2 discloses a shielded cable having a quad structure formed by twisting four insulated electric wires (four core wires) at one time. A metal foil is formed around the four core wires, a metal braid is formed on the outer circumferential surface of the metal foil, and a sheath is formed is formed the outer circumferential surface of the metal braid.

Patent document 3 discloses a shielded cable having a structure formed by twisting three insulated electric wires (three core wires) at one time. A tubular member containing a magnetic powder is wound laterally (more strictly, spirally) around the three core wires and a sheath is formed on the circumferential surface of the tubular member.

Two-core shielded cables and single-core shielded cables are also known as disclosed in Patent documents 4 and 5. Patent document 4 discloses a shielded cable in which a metal foil is wound laterally (more specifically, spirally) around two parallel insulated electric wires (two core wires) and a resin tape is formed on the outer circumferential surface of the metal foil.

Patent document 5 discloses a shielded cable in which a metal foil is provided around insulated electric wire along a length of the cable, and a sheath is formed on the outer circumferential surface of the metal foil.

Patent document 1: JP-A-2015-72774

Patent document 2: JP-A-2003-132743

Patent document 3: JP-A-2015-153497

Patent document 4: JP-A-2015-185527

Patent document 5: JP-A-2007-265797

### SUMMARY OF THE INVENTION

It is preferable that shielded cables is stable in characteristic impedance. However, in 2-core shielded cables in which two insulated electric wires are covered with a metal foil along the length of the electric wire and a sheath is formed on the outer circumferential surface of the metal foil by extrusion molding, a sheath resin presses the metal foil during extrusion molding. Thereby, the metal foil is bent inward.

FIG. 7 is a sectional view of a 2-core shielded cable as a first referential example. FIG. 8 is a sectional view of a 3-core shielded cable as a second referential example. As shown in FIG. 7, in the 2-core shielded cable in which two insulated electric wires are covered with a metal foil MF such that opposite sides of the metal foil MF come into with each other, the metal foil MF is bent inward at central portions (bending positions BP) of the longitudinal sections of an elliptical shape in a cross section. This raises a problem that the impedance between the two core wires may be rendered unstable to lower the shielding effect.

In contrast, in the 3-core shielded cable shown in FIG. 8, the shape of the metal foil MF is less prone to deteriorate than in the 2-core shielded cable, that is, the above problem is less prone to occur. In the 2-core shielded cable, since the number of bending positions BP is as small as two, force tends to be concentrated at the two locations during extrusion molding. On the other hand, in the 3-core shielded cable, since the number of bending positions BP is increased to three, force is distributed more during extrusion molding and hence the shape of the metal foil MF is less prone to deteriorate, that is, the above problem is less prone to occur. In shielded cables having four or more cores, the shape of the metal foil MF is even less prone to deteriorate. As described above, 2-core shielded cables are prone to the problem of which the shielded cables disclosed in Patent documents 1-3 are free.

The shielded cable disclosed in Patent document 5 has no bending position at all. It can therefore be said that 2-core shielded cables are prone to the problem of which the shielded cable disclosed in Patent document 5 is free.

One measure against the above problem would be to provide interstitial strings IS inside the metal foil. FIG. 9 is a sectional view of a shield cable as a third referential example. As shown in FIG. 9, interstitial strings IS are disposed beside two core wires and a metal foil MF is formed around the two core wires and the interstitial strings IS. The interstitial strings IS prevent the metal foil MF from losing its original shape. However, since this configuration requires a step of providing the interstitial strings IS inside the metal foil MF, manufacture of the shield cable takes longer time and requires an increased number of working steps.

On the other hand, the problem of bending the metal foil tends to be solved by winding the metal foil laterally as in the shield cable disclosed in Patent document 4. That is, where the metal foil is wound laterally around the two insulated electric wires, since the metal foil can be wound around the insulated wires while being stretched, the metal foil can be made less prone to bend by increasing its tension. However, manufacture of the shield cable takes longer time and requires a larger number of working steps when the metal foil is wound laterally than when the metal foil is wound longitudinally (more specifically, the metal foil is longitudinally wound around the electric wires such that opposite sides of the metal foil in the length of the electric wire come in contact with each other along the length of the electric wire).

As described above, in 2-core shielded cables, it is difficult to attain both of stabilization of the characteristic impedance and reduction of the number of working steps.

The present invention has been made to solve the above problems, and an object of the invention is therefore to provide a 2-core shielded cable and a wire harness capable of attaining both of stabilization of the characteristic impedance and reduction of the number of working steps.

The present invention provides a 2-core shielded cable having two electric wires, a metal film which is provided along a length of the electric wire so as to cover the two electric wires, and a sheath which is formed around the metal film in a filled state. The metal film includes a film and a metal layer, and the thickness of the film is larger than or equal to 20 m.

According to this 2-core shielded cable, since the metal film is provided along the length of the electric wire so as to cover the two electric wires, the number of working steps can be made smaller than in a case of lateral winding. Furthermore, since the metal film includes the film and the metal layer and the thickness of the film is larger than or equal to 20 μm, bending of the metal film can be suppressed by the thick film even if force acts on the metal film when the sheath is formed by extrusion molding. The characteristic impedance is therefore not prone to become unstable. Thus, both of stabilization of the characteristic impedance and reduction of the number of working steps can be attained.

In the above 2-core shielded cable, it is preferable that a braid is provided between the metal film and the sheath and is formed by braiding metal wires.

In the 2-core shielded cable, the braid is provided between the metal film and the sheath and is formed by braiding metal wires. Thus, when, for example, the 2-core shielded cable is connected to a shielded connector, the braid can be connected to the shielded connector so that no unshielded portion is formed. As a result, noise leakage and influence of external noise through an unshielded portion can be prevented. Further, the metal film can be prevented from breaking when, for example, it is connected to a shielded connector by pulling the former to the latter.

The present invention also provides a wire harness having the above 2-core shielded cables; and another member which contains a plasticizer and is provided adjacent to the 2-core shielded cable.

This wire harness is equipped with the 2-core shielded cable and the other cable which contains a plasticizer and is disposed adjacent to the 2-core shielded cable. Thus, a phenomenon can be suppressed that plasticizer contained in the other cable evaporates in a high-temperature environment and moves to the insulators of the insulated electric wires to increase the permittivity of the insulators and lower their shielding performance.

The present invention can provide a 2-core shielded cable and a wire harness capable of attaining both of stabilization of the characteristic impedance and reduction of the number of working steps.

### BRIEF DESCRIPTION OF THE DRAWINGS

FIG. 1 is a perspective view of a wire harness including a 2-core shielded cable according to an embodiment of the present invention.

FIG. 2 is a perspective view of the 2-core shielded cable shown in FIG. 1.

FIG. 3 is a sectional view of the 2-core shielded cable shown in FIG. 1.

FIG. 4 is a graph showing characteristic impedance characteristics of Example of the 2-core shielded cable according to the embodiment and Comparative Example.

FIG. 5 is a graph showing leakage attenuation characteristics of Example of the 2-core shielded cable according to the embodiment and Comparative Example.

FIG. 6 is a sectional view of part of FIG. 3.

FIG. 7 is a sectional view of a 2-core shielded cable as a first referential example.

FIG. 8 is a sectional view of a 3-core shielded cable as a second referential example.

FIG. 9 is a sectional view of a shielded cable as a third referential example.

### DESCRIPTION OF THE PREFERRED EMBODIMENT

The present invention will be hereinafter described by way of a preferred embodiment. The invention is not limited to the following embodiment, and modifications can be made as appropriate without departing from the spirit and scope of the invention. In the following embodiment, part of the components will not be described or shown in the drawings. However, it goes without saying that known techniques can be applied as appropriate to the details of techniques that will not be described or shown in the drawings in such a range as not to be contradictory to the following description.

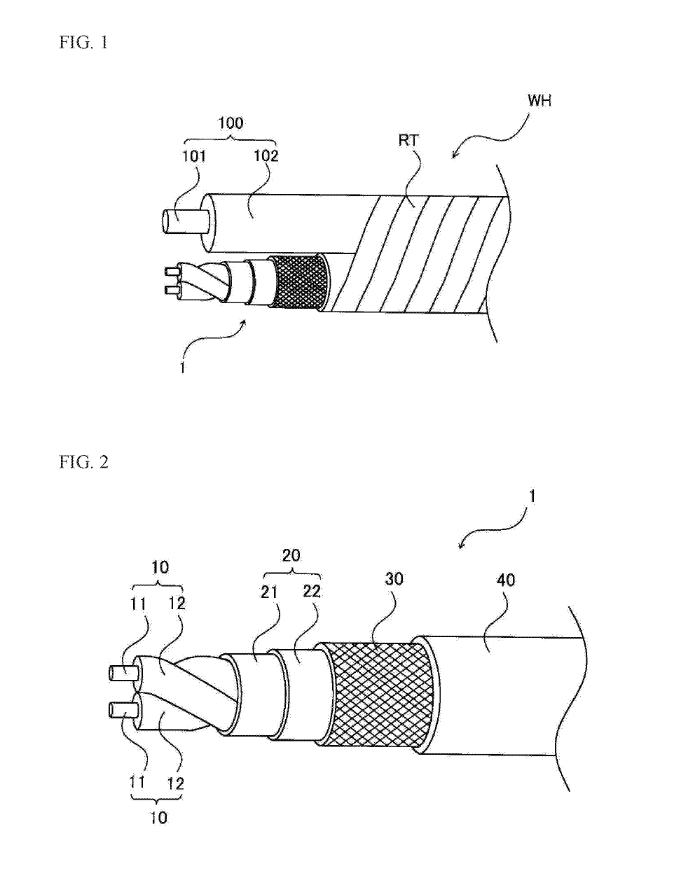

FIG. 1 is a perspective view of a wire harness WH including a 2-core shielded cable 1 according to the embodiment of the present invention. As shown in FIG. 1, the wire harness WH has the 2-core shielded cable 1 and another cable (another member) 100.

The other cable 100 is, for example, a thick electric wire such as a power line or a thin electric wire such as a signal line, and is equipped with a conductor 101 and an insulator 102 which surrounds the conductor 101. The insulator 102 includes a plasticizer such as PVC (polyvinyl chloride). A resin tape RT is wound around the combination of the 2-core shielded cable 1 and the other cable 100 or a corrugated tube (not shown), terminals (not shown), connectors (not shown), or the like are attached to them.

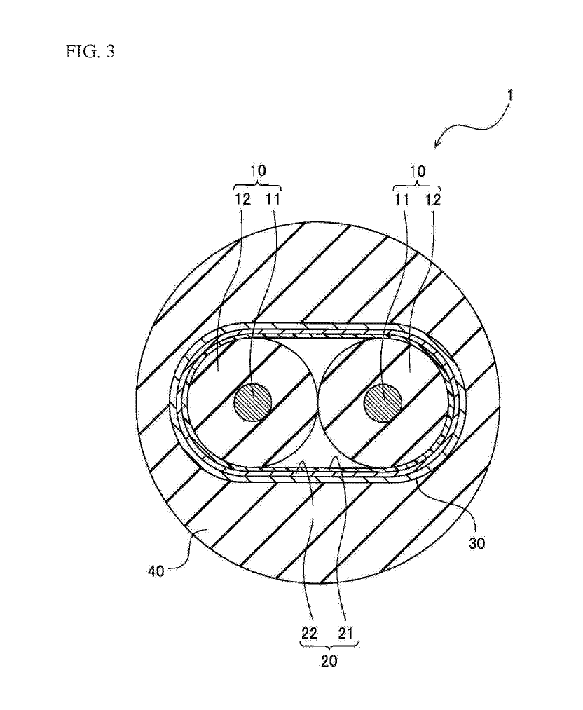

FIG. 2 is a perspective view of the 2-core shielded cable 1 shown in FIG. 1. FIG. 3 is a sectional view of the 2-core shielded cable 1 shown in FIG. 1. As shown in FIGS. 2 and 3, the 2-core shielded cable 1 is equipped with two insulated electric wires (electric wires) 10, a metal film 20, a braid 30, and a sheath 40.

Each insulated electric wire 10 has a conductor 11 and an insulator 12 formed around the conductor 11. Examples of the conductor 11 are a soft copper wire, a silver-plated soft copper wire, a tin-plated soft copper wire, and a tin-plated copper alloy wire. Although in the embodiment the conductor 11 is formed by a single element wire, it may be composed of two or more element wires. The insulator 12 which is a member for covering the conductor 11 is made of PE (polyethylene), PP (polypropylene), or the like. The relative permittivity of the insulator 12 is smaller than or equal to 3.0.

The metal film 20 has a two-layer structure including of a film 21 and a metal layer 22. The film 21 is a non-conductive resin film and is made of a PET (polyethylene terephthalate) resin, for example, and is fine enough to prevent intrusion of plasticizer. The film 21 may be made of a fluorocarbon resin. The film 21 is a biaxially stretched film that is produced by stretching a thermoplastic film in two directions (vertically and horizontally) at a high temperature, and hence is strong (i.e., hardly breaks) in the vertical and horizontal directions. The metal layer 22 is a layer of a conductive metal (e.g., copper or aluminum) formed around the film 21. The metal film 20 is provided along the length of the two insulated electric wires 10 and covers the two insulated electric wires 10 in such a manner that that the metal layer 22 is located outside.

The braid 30 is knitted out of a bundle of plural wires such as soft copper wires, silver-plated soft copper wires, tin-plated soft copper wires, or tin-plated copper alloy wires. Each metal wire may be a plated fiber formed by plating a fiber with a metal. Alternatively, the braid 30 may be knitted out of a flat bundle of plural metal wires plated together.

The sheath 40 is an insulator that covers the outer circumferential surface of the braid 30. The sheath 40 is provided outside the metal film 20 and the braid 30 in a filled state. That is, the sheath 40 does not have a tube-like structure having a space inside but is provided in a solid state. The sheath 40 having such a structure is provided outside the structure having the insulated electric wires 10, the metal film 20, and the braid 30 by solid extrusion with this structure. For example, the sheath 40 is made of a PE, PP, or PVC.

In the embodiment, since the film 21 is made of a PET resin, movement of plasticizer to the insulators 12 which are made of PP or PE is prevented utilizing an SP value difference. when the sheath 40 is made of PVC, there may occur a phenomenon that plasticizer contained in the sheath 40 or the insulator 102 of the cable 100 evaporates in a high-temperature environment and moves to the insulators 12 of the insulated electric wires 10 to lower their insertion loss characteristic. In the embodiment, this phenomenon can be prevented by the film 21 which is made of a PET resin.

Furthermore, in the 2-core shielded cable 1 according to the embodiment, the thickness of the film 21 is larger than or equal to 20 μm. Thus, the thick film 21 can suppress inward bending of the metal film 20 when force acts on the metal film 20 during extrusion molding of the sheath 40.

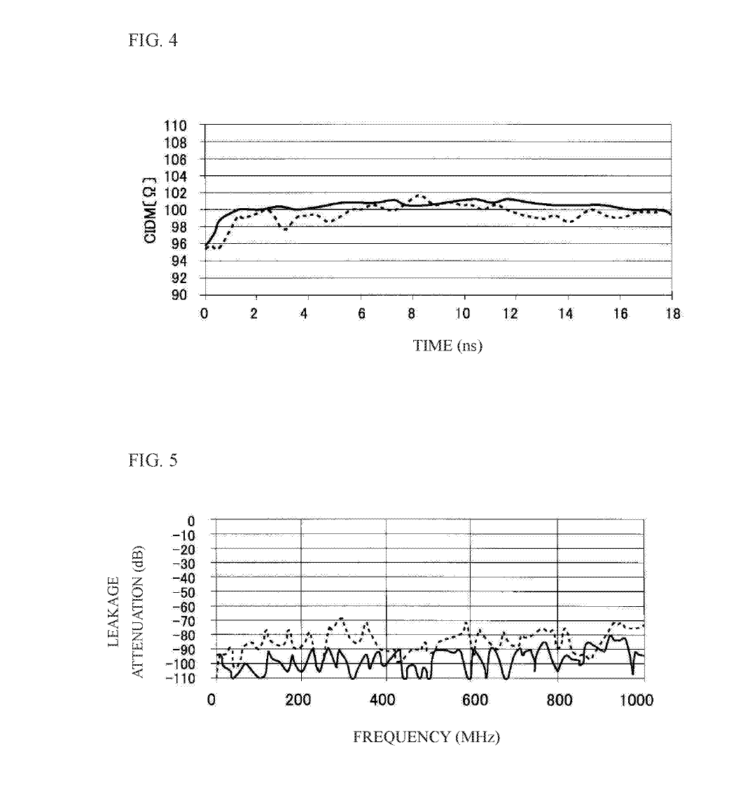

Next, Example of the 2-core shielded cable 1 according to the embodiment and Comparative Example will be described. FIGS. 4 and 5 are graphs showing characteristics, more specifically, characteristic impedance characteristics and leakage attenuation characteristics, of Example of the 2-core shielded cable 1 and Comparative Example. In FIGS. 4 and 5, the characteristics of Example are represented by a solid line and the characteristics of Comparative Example are represented by a broken line.

In Example of the 2-core shielded cable 1 of the present invention, each conductor 11 used a soft copper twisted wire of 7/0.16 wires/mm and 0.48 mm in outer diameter. As a result, the size of each conductor 11 was AWG 26/0.13 sq. Each insulator 12 used 0.36 mm in thickness and 1.20±0.05 mm in outer diameter and was made of crosslinking HDPE (high-density polyethylene). The two insulated electric wires 10 were 30 mm in twisting pitch and 2.40 mm in twisting outer diameter.

The film 21 was a PET film of 25 μm in thickness, and the metal layer 22 was made of aluminum. The insulated electric wires 10 are covered by the metal film 20 and thereby an outer diameter becomes 2.51 mm. The braid 30 was a tin-plated soft copper wire braid that was 0.08 mm in element wire diameter, 8 in the number of element wires per group, 16 in the number of groups, 32.6 mm in pitch, 85% or more in density, and 2.86 mm in outer diameter. The sheath 40 used about 0.570 mm in thickness and 4.00±0.2 mm in outer diameter and was made of heat-resistant PVC (3.000 hours at 105° C.).

On the other hand, Comparative Example (2-core shielded cable) was the same as Example of the 2-core shielded cable 1 according to the embodiment except that the film 21 was a PET film of 10 μm in thickness.

As shown in FIG. 4, whereas the characteristic impedance of Comparative Example varied in a range of 98 to 102Ω, that of Example fell within a range of 100 to 102Ω. It was therefore found that the characteristic impedance of Example of the 2-core shielded cable 1 according to the embodiment is more stable than that of Comparative Example.

As shown in FIG. 5, whereas the leakage attenuation of Comparative Example was −68 dB around 300 MHz, that of Example remained −80 dB even at 900 MHz. It was therefore found that the leakage attenuation characteristic of Example of the 2-core shielded cable 1 according to the embodiment is better than that of Comparative Example.

In summary, Example of the 2-core shielded cable 1 according to the embodiment (PET film thickness: 25 μm) was better than Comparative Example (PET film thickness: 10 μm) in both of the characteristic impedance and the leakage attenuation.

Although not shown in any drawings, results similar to the case of the PET film being 25 μm in thickness were obtained also in the case of the PET film being 20 μm in thickness. Furthermore, results similar to the case of the PET film were obtained also in the case of a fluorine film.

As described above, in the 2-core shielded cable 1 according to the embodiment, since the metal film 20 is provided along the length of the insulated electric wires 10 and covers the insulated electric wires 10, the number of working steps can be made smaller than in a case of lateral winding. Furthermore, since the metal film 20 is composed of the film 21 and the metal layer 22 and the thickness of the film 21 is larger than or equal to 20 μm, bending of the metal film 20 can be suppressed by the thick film 21 even if force acts on the metal film 20 when the sheath 40 is formed by extrusion molding. The characteristic impedance is therefore not prone to become unstable. Thus, both of stabilization of the characteristic impedance and reduction of the number of working steps can be attained.

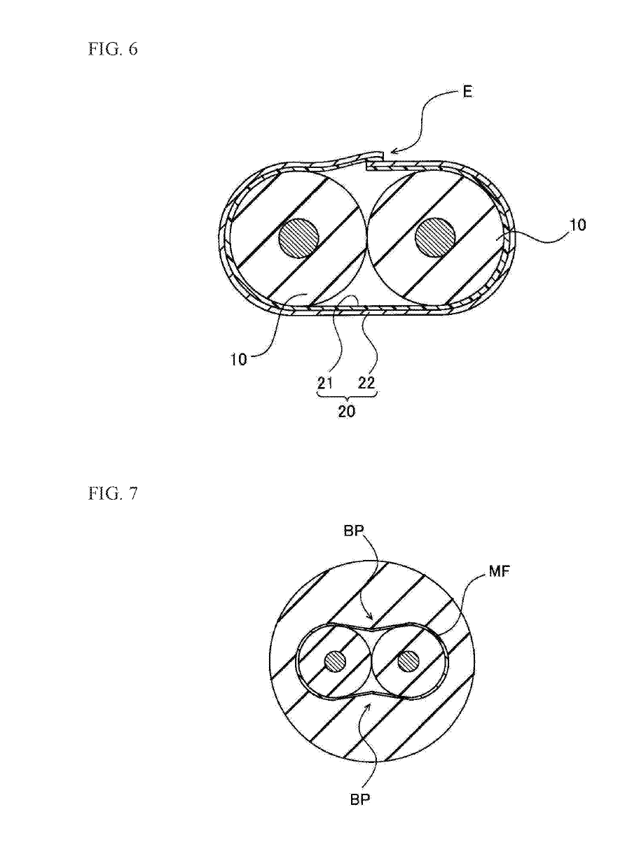

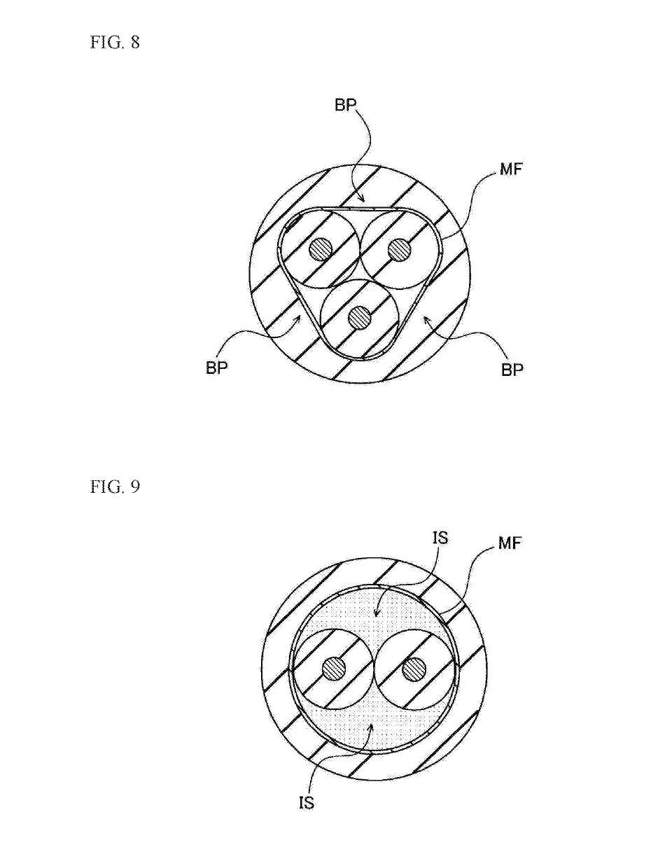

FIG. 6 is a sectional view of part of FIG. 3. In the 2-core shielded cable 1 according to the embodiment, in performing terminal forming work, an outside end portion E of the metal film 20 which covers the insulated electric wires 10 longitudinally is cut away with a tool having a sharp tip portion by having it hooked on the outside end portion E. Hooking the tip portion of the tool on the outside end portion E is difficult if the metal film 20 is bent inward there. Since the metal film 20 is not prone to bend inward, the 2-core shielded cable 1 according to the embodiment is free of the problem that hooking the tip portion of the tool on the outside end portion E of the metal film 20 is made very difficult.

The braid 30 formed by braiding metal wires is provided between the metal film 20 and the sheath 40. Thus, when, for example, the 2-core shielded cable 1 is connected to a shielded connector, the braid 30 can be connected to the shielded connector so that no unshielded portion is formed. As a result, noise leakage through an unshielded portion and influence of external noise can be prevented. And the metal film 20 can be prevented from breaking when, for example, it is connected to a shielded connector by pulling the former to the latter.

The presence of the braid 30 provides an effect of making the 2-core shielded cable 1 less prone to be disconnected from a shielded connector in a case that the braid 30 is connected to the shielded connector, contributing to securing necessary strength. In particular, in shielded cables for high-speed digital signal transmission, noise leakage and influence of external noise become remarkable if their characteristic impedance is rendered unstable. Use of the braid 30 whose breaking strength is higher than or equal to 100 N makes it possible to prevent the 2-core shielded cable 1 from coming off a shielded connector even if one end of the 2-core shielded cable 1 is attached to the shielded connector and certain work is done while its other end is pulled.

The wire harness WH according to the embodiment is equipped with the 2-core shielded cable 1 and the other cable 100 which contains a plasticizer and is disposed adjacent to the 2-core shielded cable 1. Thus, a phenomenon can be suppressed that plasticizer contained in the insulator 102 of the cable 100 evaporates in a high-temperature environment and moves to the insulators 12 of the insulated electric wires 10 to increase the permittivity of the insulators 12 and lower their shielding performance.

Although the invention has been described above by way of the embodiment, the invention is not limited to the above embodiment. Various modifications can be made of the embodiment and known techniques may be added to the embodiment without departing from the spirit and scope of the invention.

For example, although the 2-core shielded cable 1 according to the embodiment is equipped with the braid 30, the invention is not limited to this case, that is, the 2-core shielded cable 1 need not always be equipped with the braid 30. In certain cases, the metal film 20 may be such that the metal layer 22 is located inside.

Although the embodiment assumes that the 2-core shielded cable 1 is to be attached to a shielded connector, it may be attached to things other than a shielded connector.

What is claimed is:

1. A 2-core shielded cable comprising:
two electric wires;
a metal film which is provided along a length of the electric wire so as to cover the two electric wires, and
a sheath which is formed around the metal film in a filled state,
wherein the metal film includes a film and a metal layer, and
wherein the thickness of the film is larger than or equal to 20 μm.

2. The 2-core shielded cable according to claim 1, further comprising a braid which is provided between the metal film and the sheath and is formed by braiding metal wires.

3. A wire harness comprising:
the 2-core shielded cable according to claim 1; and
another member which contains a plasticizer and is provided adjacent to the 2-core shielded cable.
